(19) United States
(12) Patent Application Publication
(10) Pub. No.: US 2010/0321356 A1
(43) Pub. Date: Dec. 23, 2010

(54) THIN-FILM TRANSISTOR, PHOTODETECTOR CIRCUIT INCLUDING THE SAME, AND DISPLAY DEVICE

(75) Inventors: Christopher Brown, Oxford (GB); Kohhei Tanaka, Osaka (JP); Hiromi Katoh, Osaka (JP)

Correspondence Address: NIXON & VANDERHYE, PC, 901 NORTH GLEBE ROAD, 11TH FLOOR, ARLINGTON, VA, 22203, US

(73) Assignee: SHARP KABUSHIKI KAIHSA, OSAKA-SHI OSAKA (JP)

(21) Appl. No.: 12/867,124

(22) PCT Filed: Feb. 16, 2009
(86) PCT No.: PCT/JP2009/052499

§ 371 Date: Aug. 11, 2010

(51) Int. Cl. G09G 5/00; H01L 33/00

(52) U.S. Cl. 345/207; 257/59; 257/E33.053

(57) ABSTRACT

A thin-film transistor (1) of the present invention which (i) is used in a path in which a current flows in a given single direction and (ii) has high-concentration impurity regions (3 and 4) which are provided on both sides of a channel region (5) has a low-concentration impurity region (6) which is provided to be sandwiched only between (i) one of the high-concentration impurity regions (3 and 4) into which carriers corresponding to a polarity of the high-concentration impurity regions (3 and 4) move in accordance with the given single direction and (ii) the channel region (5). This provides a thin-film transistor which is less affected by a display signal and carries out on/off control with respect to an output signal of a photodetector that is provided in a pixel which constitutes a display screen of a display device.

### TECHNICAL FIELD

The present invention relates to a thin-film transistor, a photodetector circuit including the thin-film transistor, and a display device in which the photodetector circuit is provided.

### BACKGROUND ART

A display device has been recently developed in which a plurality of photodetectors are provided at regular intervals in a display region of a display panel including a plurality of pixels and the plurality of photodetectors are provided in the respective plurality of pixels. It is possible to provide such a display device with not only a general display function but also various functions each employing a photodetector as mentioned above such as a light controlling function of a backlight, a touch panel function, an OCR function for character recognition, and a security function such as fingerprint authentication.

(Conventional Photodetector Circuit)

FIG. 7 is a block diagram illustrating an arrangement of a display region of such a display device and a circuit block which drives the display region. The block diagram is disclosed in Patent Literature 1.

Each of a plurality of pixels constituting a display region 70 includes a display pixel 86 and a photodetector pixel 87.

The display pixels 86 are provided at or in the vicinity of intersections of source signal lines 83 and gate signal lines 82a which are provided vertically and transversely, respectively. The display pixel 86 includes (i) a thin-film transistor (hereinafter abbreviated as TFT) 92, (ii) a liquid crystal capacitor which is defined by (a) a pixel electrode 101 connected to one end of the TFT 92 and (b) a common electrode which is provided so as to face the pixel electrode 101, and (iii) a storage capacitor 95 which is defined by the pixel electrode 101 and a common signal line 91.

A photodetector pixel 87 includes a publicly-known CMOS photodetector circuit in which three TFTs 102a, 102b, and 102c are used as switching elements. The photodetector circuit includes a TFT 104 operating as a photodiode, an integral capacitor 103 by which a precharge voltage is stored, the TFT 102b operating as a source follower, the TFT 102a operating as a switching element which applies the precharge voltage to the integral capacitor 103, and the TFT 102c selectively supplying a source follower output signal of the TFT 102b to a photodetector output signal line 85.

One terminal of the TFT 102a is connected to a precharge voltage signal line 84 and the other terminal of the TFT 102a is connected to a gate electrode of the TFT 102b. A gate electrode of the TFT 102a is connected to a gate signal line 82c. Respective one terminals of the TFT 104, the TFT 102b, and the integral capacitor 103 which serve as photodetector elements are connected to the common signal line 91. The respective other terminals of the TFT 104 and the integral capacitor 103 are connected to the gate electrode of the TFT 102b. A gate electrode of the TFT 102c is connected to a gate signal line 82b.

The gate signal line 82a selecting the display pixel 86 is driven by a gate driver circuit 72a. The gate signal lines 82b and 82c causing the photodetector pixel 87 to operate are driven by a gate driver circuit 72b. The precharge voltage signal line 84 and the photodetector output signal line 85 are driven by a photodetector processing circuit 78. The source signal line 83 is driven by a source driver 74.

When the TFT 102a turns on in response to an ON voltage applied to the gate signal line 82c, the precharge voltage applied from the photodetector processing circuit 78 to the precharge voltage signal line 84 is applied to the one terminal of the TFT 104 and the integral capacitor 103. This causes the integral capacitor 103 to store the precharge voltage and also causes a reverse voltage to be applied across the TFT 104 serving as the photodetector element. Note that the precharge voltage is a voltage (having not less than a threshold voltage of Vth) at which the TFT 102b turns on.

When the TFT 104 is exposed to light irradiation in this state, a current leak occurs in accordance with an intensity of the light in TFT 104. This causes an electric charge stored by the integral capacitor 103 to be discharged, via channels of the TFT 104, in accordance with the intensity of the light. Accordingly, a change in voltages at both ends of the integral capacitor 103 due to the light irradiation to which the TFT 104 is exposed causes a change in gate voltage of the TFT 102b.

Namely, as the light to which the TFT 104 is exposed becomes more intense, a larger amount of the electric charge stored by the integral capacitor 103 is discharged. Therefore, in a case where an amount of the light to which the TFT 104 is exposed is 0 (zero), the TFT 102b turns on. In a case where the TFT 104 is exposed to a larger amount of the light, a gate of the TFT 102b is gradually closed. In a case where the TFT 104 is exposed to a sufficiently large amount of the light, the TFT 102b turns off.

When the ON voltage is applied from the gate driver circuit 72b to the gate signal line 82b, the TFT 102c turns on. Therefore, in a case where the TFT 102b turns on (i.e., in a dark state in which the TFT 104 receives no light) at this time, an electric charge of the photodetector output signal line 85 is discharged via the TFTs 102c and 102b into the common signal line 91 (may be charged depending on an electric potential of the common signal line 91). A change in electric charge of the photodetector output signal line 85 due to a change in output voltage of the TFT 102b causes a change in electric potential of the photodetector output signal line 85. There occurs no change in electric charge of the photodetector output signal line 85, provided that the TFT 102b turns off (i.e., a bright state in which the TFT 104 receives light) while the TFT 102c turns on.

As described earlier, the output voltage from the photodetector pixel 87 changes between a voltage obtained in the dark state and a voltage obtained in the bright state. Then, the output voltage is detected by the photodetector processing circuit 78 via the photodetector output signal line 85.

Non Patent Literature 1 discloses a photodetector circuit in which the three TFTs 102a, 102b, and 102c have been replaced with one (1) TFT. Note that such a photodetector circuit is to be explained in detail later in the section of Description of Embodiments.

(Conventional TFT Structure)

According to the TFT 102b as mentioned above which carries out a function of changing an output signal of a photodetector in accordance with an intensity of light, a deterioration in characteristics of a TFT with time (e.g., a deviation of a threshold voltage at which the TFT turns on from a designed voltage) is prevented, and a GOLD structure (see (c) of FIG. 1) is employed so that the characteristics of the TFT are stabilized.

Namely, according to the TFT 102b constituted as an N-type TFT, a pair of high-concentration impurity regions (a source and a drain) 81 and 82 formed by carrying out implantation of a high concentration N-type impurity with respect to a silicon film serving as an operating layer are provided so that a channel region 83 is sandwiched between the pair. Low-concentration impurity regions (hereinafter referred to as LDD (Lightly Doped Drain) regions) 84 and 85 formed by carrying out implantation of a low concentration N-type impurity with respect to the silicon film are provided between the respective high-concentration impurity regions and the channel region 83.

A gate electrode 80 of the TFT 102b has an LDD structure in which not only the gate electrode 80 and the channel region 83 face each other but also (i) the gate electrode 80 and (ii) the LDD regions 84 and 85 face and overlap each other. Such an LDD structure is referred to as a GOLD (Gate-drain Overlapped LDD) structure (refer to Patent Literature 2, for example).

In the case of the structure illustrated in (c) of FIG. 1, the high-concentration impurity region 81 serves as a drain which is connected to the common signal line 91 of FIG. 7, and the high-concentration impurity region 82 serves as a source connected to a drain of the TFT 102c of FIG. 7.

Patent Literature 1

Japanese Patent Application Publication, Tokukai, No. 2006-267967 A (Publication Date: Oct. 5, 2006)

Patent Literature 2

Japanese Patent Application Publication, Tokukai, No. 2000-299469 A (Publication Date: Oct. 24, 2000)

Non Patent Literature 1

A Continuous-Grain Silicon-System LCD With Optical Input Function (IEEE JOURNAL OF SOLID-STATE CIRCUITS, VOL. 42, No. 12, PP2904-2912 DECEMBER 2007; Chris J. Brown, Hiromi Kato, Kazuhiro Maeda, and Ben Hadwen)

### SUMMARY OF INVENTION

However, the aforementioned conventional arrangements of a photodetector circuit and a TFT have a problem that a gate electric potential of a source follower TFT (e.g., the TFT 102b) carrying out a function important for an output voltage of a sensor is highly likely to be affected by an influence of a display signal supplied to a pixel electrode and this causes a deterioration in sensor characteristics.

This is because the GOLD structure of the TFT 102b causes a parasitic capacitance 105 generated between the gate electrode 80 of the TFT 102b and the pixel electrode 101 to be large.

A root cause of the generation of the parasitic capacitance 105 is exemplified by the fact that the pixel electrode 101 (see FIG. 7) is actually provided beyond a region of the display pixel 86 so as to cover a region of the photodetector pixel 87 as well and this causes the gate electrode 86 of the TFT 102b and the pixel electrode 101 to face each other.

According to the TFT 102b having the GOLD structure, the gate electrode 80 is forced to be as large as the LDD regions 84 and 85 which the gate electrode 80 overlaps and this enlarges an area in which the gate electrode 86 and the pixel electrode 101 face each other. This leads to an increase in parasitic capacitance 105.

Here, a state in which a gate electrode of a source follower TFT and a pixel electrode face each other is to be checked with reference to FIG. 5 illustrating an embodiment of the present invention. FIG. 5 is a plan view illustrating a peripheral part of a photodetector circuit when an R pixel, a G pixel, and a B pixel of a display device in which a color display is carried out are seen in plan view. FIG. 5 shows the photodetector circuit including (i) a TFT: M1 as the source follower TFT covered with a pixel electrode 350 of the pixel and (ii) a photodiode 30 of a PIN type covered with a pixel electrode 35B of the B pixel.

The reason for such covering of a photodetector circuit provided in a pixel with a pixel electrode is to provide a display device in which the pixel can secure a desired aperture ratio and a bright display can be carried out while the photodetector circuit is provided in the pixel.

As described earlier, according to the arrangement in which a gate electrode of a source follower TFT and a pixel electrode face each other, a display signal which constantly fluctuates enters into the pixel electrode. This causes a state in which the display signal fluctuates on the gate electrode. In such a state, the display signal has an influence on a gate electric potential of the source follower TFT via a parasitic capacitance, and the influence becomes greater as the parasitic capacitance increases. Thus, a larger parasitic capacitance causes a more remarkable deterioration in sensor characteristics such as a fall in output voltage.

The present invention has been made in view of the problems, and its object is to provide (i) a thin-film transistor which is less affected by a display signal and carries out on/off control with respect to an output signal of a photodetector that is provided in a pixel which constitutes a display screen of a display device, (ii) a photodetector circuit which includes the thin-film transistor so as to have stable characteristics, and (iii) a display device which includes the thin-film transistor so as to have stable functions.

In order to attain the object, a thin-film transistor in accordance with the present invention which (i) is used in a path in which a current flows in a given single direction and (ii) has first and second high-concentration impurity regions which are provided on both sides of a channel region, the thin-film transistor further has a low-concentration impurity region which is provided to be sandwiched only between (i) one of the first and second high-concentration impurity regions into which carriers corresponding to a polarity of the first and second high-concentration impurity regions move in accordance with the given single direction and (ii) the channel region.

According to the arrangement, in the case of a thin-film transistor which is used in a path in which a current flows in a given single direction, a side area of the thin-film transistor into which carriers corresponding to a polarity of the high-concentration impurity regions move is specified. For example, in a case where the high-concentration impurity regions have an N-type polarity, the side area into which electrons move in a direction opposite to the given single direction is specified. In a case where the high-concentration impurity regions have a P-type polarity, the side area into which electron holes move in a direction identical to the given single direction is specified.

According to the arrangement in which a side area of the thin-film transistor into which carriers corresponding to a polarity of the high-concentration impurity regions move is specified, if one of the high-concentration impurity regions to which the carriers move and the channel region are brought into contact with each other in the side area, hot carriers causing a deterioration in characteristics of the thin-film transistor are generated in the vicinity of a part where the one of the high-concentration impurity regions and the channel region are in contact with each other. Namely, few hot carriers are generated between (i) the other of the high-concentration impurity regions located in the other side area opposite to the specified side area and (ii) the channel region.

In view of the circumstances, in order to prevent the generation of the hot carriers, the thin-film transistor of the present invention has an LDD structure (a one-sided LDD structure) in which the low-concentration impurity region is sandwiched only between (i) one of the high-concentration impurity regions located in the specified side area and (ii) the channel region. Namely, according to the structure, no low-concentration impurity region is sandwiched between (i) the other of the high-concentration impurity regions located in the other side area opposite to the specified side area and (ii) the channel region.

The thin-film transistor of the present invention having the structure can further reduce an area of a gate electrode as compared to a thin-film transistor having a GOLD structure in which low-concentration impurity regions are provided on both sides of a channel region and the gate electrode and both the low-concentration impurity regions face and overlap each other.

Namely, it is possible to employ a one-sided GOLD structure in which a gate electrode and a low-concentration impurity region constituting the one-sided LDD structure face and overlap each other. Alternatively, it is possible to employ a structure in which a gate electrode and a low-concentration impurity region do not overlap each other but the low-concentration impurity region and a channel region merely face and overlap each other.

As a result, a parasitic capacitance of smaller than a conventional one is generated in an arrangement in which a gate electrode and an electrode of another circuit or a wire face each other, as in a case where the thin-film transistor of the present invention is (i) provided in a pixel which constitutes a display screen of a display device and (ii) covered with a corresponding pixel electrode of the pixel. This causes the thin-film transistor to be less affected by a signal supplied to the electrode of the another circuit, and consequently to be stabilized.

Note that, in a case where the one-sided GOLD structure is employed in which not only a gate electrode and a channel region face each other but also the gate electrode and a low-concentration impurity region face and overlap each other, it is possible to further stabilize characteristics of a thin-film transistor.

A photodetector circuit in accordance with the present invention includes a photodetector element, the thin-film transistor as mentioned above being used as switching means for causing a voltage which varies in accordance with an amount of light received by the photodetector element to be outputted.

According to the arrangement, the photodetector circuit to which the present invention is directed includes a thin-film transistor used as switching means for causing a voltage which varies in accordance with an amount of light received by a photodetector element to be outputted. The thin-film transistor is provided in a path in which a current flows in a given single direction, and can output a voltage equal to a subtraction of a threshold voltage from a gate electrode. The thin-film transistor functions as a source follower transistor. Note that the thin-film transistor is also referred to as a voltage follower transistor.

Such a photodetector circuit, which is constituted by a small number of elements, has an advantage of being easily provided in a pixel constituting a display screen of a display device. Further, it is possible to design a pixel structure in which (i) a single photodetector circuit is provided for each pixel or every given number of pixels and (ii) a pixel electrode to which a display signal is supplied covers the single photodetector circuit so that a pixel can secure a desired aperture ratio while the photodetector circuit is provided in the pixel.

In the case of such a pixel structure, detection of an amount of light can be stably carried out because the photodetector circuit in accordance with the present invention includes the thin-film transistor of the present invention having the one-sided LDD structure or the one-sided GOLD structure in which a gate electrode has a small area. Accordingly, it is possible to provide various stable functions such as a touch panel function, an OCR function, and a security function such as fingerprint authentication for a display device in which the photodetector circuit in accordance with the present invention is provided.

Furthermore, it is possible to bring about various effects of (i) achieving a quick response speed at which the photodetector circuit detects an amount of received light because a parasitic capacitance, defined by a gate electrode and an electrode of another circuit or a wire which faces the gate electrode, is reduced and (ii) widening a dynamic range because a feed-through voltage due to a parasitic capacitance is reduced.

Moreover, since the thin-film transistor has the one-sided LDD structure or the one-sided GOLD structure of the present invention, the thin-film transistor has a smaller capacitance. This causes a reduction in load, on a source bus line in a case where (i) a power supply voltage is supplied to the thin-film transistor through the source bus line and (ii) a signal is read out from the thin-film transistor through the source bus line. This allows a detection signal supplied from a photodetector element to be read in a shorter time. A reduction in the time required to read the detection signal is greatly advantageous for the purpose of realizing a higher resolution in photodetection.

Note that such an effect is more remarkably shown in the one-sided LDD structure because the thin-film transistor, which has a smaller capacitance in the one-sided LDD structure than in the one-sided GOLD structure, causes a further reduction in load on the source bus line and allows a further reduction in the time required to read the detection signal.

The photodetector circuit in accordance with the present invention can have a first arrangement further including: a capacitor having a first electrode which is connected to a selection signal input line, the photodetector element being a photodiode having (i) a third electrode which is connected to a gate of the thin-film transistor used as the switching means and to a second electrode of the capacitor and (ii) a fourth electrode which is connected to an initialization signal input line, the fourth electrode being arranged to (i) receive, during a reset period, a first voltage which causes a forward voltage to be applied across the photodiode so that the capacitor is charged until a set voltage is applied across the capacitor and (ii) receive, during a photodetection period, a second voltage which causes a reverse voltage to be applied across the photodiode, the first electrode of the capacitor being arranged to receive, during a detection signal reading period, from the selection signal input line, a third voltage which causes a rapid increase in electric potential of the gate.

The photodetector circuit in accordance with the present invention can have a second arrangement further including: a capacitor having a first electrode to which a constant voltage is applied; and a switching transistor having (i) a drain-source electroconductive path which is connected in series to a drain-source electroconductive path of the thin-film transistor used as the switching means and (ii) a gate which is connected to a selection signal input line, the photodetector element being a photodiode having (i) a third electrode which is connected to a gate of the thin-film transistor and to a second electrode of the capacitor and (ii) a fourth electrode which is connected to an initialization signal input line, the fourth electrode being arranged to (i) receive, during a reset period, a first voltage which causes a forward voltage to be applied across the photodiode so that the capacitor is charged until a set voltage is applied across the capacitor and (ii) receive, during a photodetection period, a second voltage which causes a reverse voltage to be applied across the photodiode, a voltage, which varies in accordance with an amount of light received by the photodiode, being supplied from the thin-film transistor via the switching transistor, during a detection signal reading period, in response to a third voltage a third voltage which causes the switching transistor to turn on, being supplied from the selection signal input line.

The photodetector circuit in accordance with the present invention can have a third arrangement further including: a switching transistor having (i) a drain-source electroconductive path which is connected in series to a drain-source electroconductive path of the thin-film transistor used as the switching means and (ii) a gate which is connected to a selection signal input line, the photodetector element being the photodiode which is connected to a capacitor in parallel, each end of the photodiode and the capacitor being grounded, the photodetector circuit, further including, an initialization transistor having (i) source-drain connected between the other end of the photodiode and a power supply voltage whose electric potential is higher than a ground electric potential and (ii) a gate connected to an initialization signal input line, the capacitor being charged by the power supply voltage and a reverse voltage is applied across the photodiode, during a reset period, while the initialization transistor is turning on in response to a signal supplied from the initialization signal input line, and a voltage which varies in accordance with an amount of light received by the photodiode being supplied from the thin-film transistor via the switching transistor while the switching transistor is turning on in response to a signal supplied from the selection signal input line.

A comparison of the first through third arrangements shows that the photodetector circuit can be constituted by fewer elements in the second arrangement than in the third arrangement and much fewer elements in the first arrangement than in the second arrangement.

As the number of the elements is smaller, parasitic capacitances generated in the respective elements are smaller. This causes an increase in response speed of the photodetector circuit. Alternatively, as the number of the elements is smaller, an area which is required for providing the photodetector circuit is smaller. This is advantageous for the purpose of miniaturization of a device and a reduction in cost. This is advantageous for the purpose of securement of an aperture ratio as much as possible, particularly in the case of a display device in which a photodetector circuit is provided in a pixel.

A display device in accordance with the present invention includes the photodetector circuit as mentioned above provided in each of part or all of a plurality of pixels which constitute a display screen, in the each of part or all of the plurality of pixels in which the photodetector circuit is provided, the photodetector circuit being covered with a corresponding pixel electrode via which a display signal is supplied.

According to the arrangement, a photodetector circuit provided in a display device includes a thin-film transistor which has (i) the one-sided LDD structure or the one-sided GOLD structure of the present invention and (ii) a small gate electrode. This causes a parasitic capacitance generated between a pixel electrode covering the photodetector circuit and the gate electrode to be small.

For this reason, detection of an amount of light can be stably carried out by the photodetector circuit, as described earlier. Accordingly, various functions (e.g., a touch panel function, an OCR function, and a security function such as fingerprint authentication) which are provided for a display device in which the photodetector circuit is provided are stabilized.

In addition, it is possible to provide a display device which has various advantages of (i) achieving a quick response speed at which the photodetector circuit detects an amount of received light because a parasitic capacitance, defined by a gate electrode and an electrode of another circuit or a wire which faces the gate electrode, is reduced and (ii) widening a dynamic range because a feed-through voltage due to a parasitic capacitance is reduced.

Note that (i) the number of pixels in each of which a photodetector circuit is provided and (ii) a ratio of the number of the pixels to the total number of pixels can be appropriately decided in accordance with the various functions.

The display device in accordance with the present invention is arranged such that a single photodetector circuit is provided for every given number of pixels which are adjacent to each other; and a plurality of elements which constitute the single photodetector circuit are dispersed in the given number of plurality of pixels.

This allows an area, in a pixel, which is occupied by a photodetector circuit to be smaller, as compared to the case in which a plurality of elements constituting a photodetector circuit are provided in one (1) pixel. Accordingly, it is possible to increase an aperture ratio and to cause a screen of a display device in which a photodetector circuit is provided to be further brighter.

Note that a photodetector circuit having the first arrangement is the most advantageous for the purpose of increasing an aperture ratio and a response speed.

Note that a feature recited in one claim is combinable not only with a feature recited in the other claims from which the claim is dependent, but also with any other claims from which the claim is not dependent, provided that the object of the present invention can be attained.

For a fuller understanding of the nature and advantages of the invention, reference should be made to the ensuing detailed description taken in conjunction with the accompanying drawings.

### BRIEF DESCRIPTION OF DRAWINGS

FIG. 1 has cross-sectional views schematically illustrating arrangements of thin-film transistors. (a) of FIG. 1 illustrates the arrangement of the thin-film transistor having a one-sided GOLD structure of the present invention, (b) of FIG. 1 illustrates the arrangement of the thin-film transistor having a one-sided LDD structure of the present invention, and (c) of FIG. 1 illustrates the arrangement of the thin-film transistor having a conventional GOLD structure.

FIG. 2 is a block diagram schematically illustrating an arrangement of a display device in accordance with the present invention.

FIG. 3 is a circuit diagram illustrating configurations of a display circuit and a photodetector circuit which are included in a pixel circuit provided in a pixel of the display device.

FIG. 4 is a timing chart illustrating operation of the photodetector circuit.

FIG. 5 is a plan view specifically illustrating a state in which the photodetector circuit is provided in a pixel.

FIG. 6 has circuit diagrams illustrating variations of a photodetector circuit in which a thin-film transistor in accordance with the present invention is used. (a) of FIG. 6 illustrates the photodetector circuit of 3T-type, (b) of FIG. 6 illustrates the photodetector circuit of 2T-type, and (c) of FIG. 6 illustrates the photodetector circuit of 1T-type.

FIG. 7 is a circuit diagram illustrating configurations of a display circuit and a photodetector circuit which are included in a pixel circuit provided in a pixel of a conventional display device.

### REFERENCE SIGNS LIST

1 Thin-film transistor
3 High-concentration impurity region
4 High-concentration impurity region
5 Channel region
6 Low-concentration impurity region
7 Gate electrode
18b Photodetector circuit
30 Photodiode (Photodetector element)
31 Integral capacitor (Capacitor)
32 Reset signal line (Initialization signal input line)
33 Row selection signal line
35R Pixel electrode
35G Pixel electrode
35B Pixel electrode
64 TFT (Initialization Transistor)
65 TFT (Thin-film transistor, Switching means, Source follower transistor)
66 TFT (Switching transistor)
67 TFT (Thin-film transistor, Switching means, Source follower transistor)

### DESCRIPTION OF EMBODIMENTS

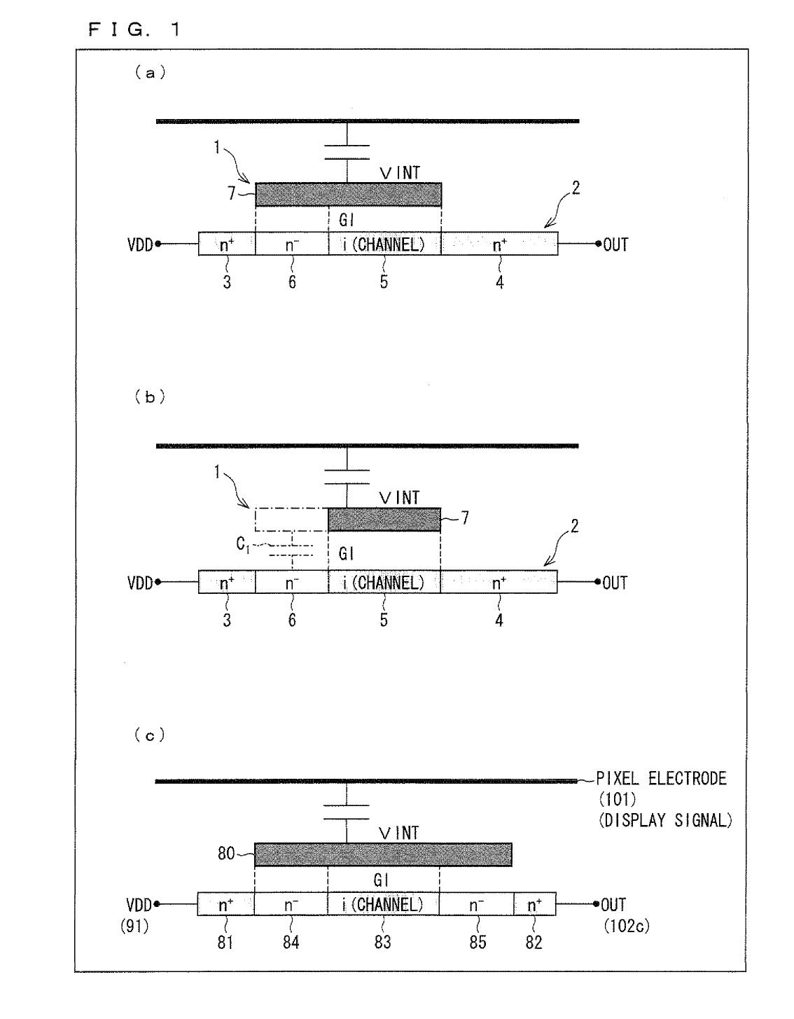

An embodiment of the present invention is described below with reference to FIGS. 1 through 6. Note that, for convenience of description, simplified drawings referred to below illustrate only main members of the embodiment of the present invention which are necessary for description of the present invention. Accordingly, a display device of the present invention can include any other member that is not illustrated in the drawings to which the present specification refers. Note also that sizes of the respective members in the drawings do not faithfully illustrate sizes of respective actual members and a dimensional ratio between the respective actual members.

(Structure of Thin-Film Transistor)

(a) and (b) of FIG. 1 schematically illustrate cross-sectional structures of a MOS (Metal Oxide Semiconductor) thin-film transistor 1. For example, a foundation insulating film is formed on a glass substrate and then a polysilicon film 2 serving as an operating layer of a TFT is formed on the foundation insulating film. A pair of high-concentration impurity regions 3 and 4, which respectively serve as a source and a drain of the TFT, are provided at both end portions of the polysilicon film 2. The high-concentration impurity region 4 is in contact with a channel region 5 serving as an intrinsic semiconductor region (I-region).

In contrast, the high-concentration impurity region 3 is not in contact with the channel region 5. Instead, a low-concentration impurity region 6 is sandwiched between the high-concentration impurity region 3 and the channel region 5. Accordingly, the thin-film transistor in accordance with the present invention has an LDD structure only on a side on which the high-concentration impurity region 3 is provided.

Note that, according to the present embodiment, (i) the high-concentration impurity regions 3 and 4 are formed by carrying out ion implantation of a high-concentration N-type impurity such as phosphorous or arsenic with respect to the polysilicon film 2 and (ii) the low-concentration impurity region 6 is formed by carrying out ion implantation of a low-concentration N-type impurity with respect to the polysilicon film 2. Therefore, each of the thin-film transistors (see (a) and (b) of FIG. 1) is an NIN transistor in which N-type impurity regions are formed on both sides of the intrinsic semiconductor region (I-region).

However, the present invention is not limited to the NIN transistor, and is also applicable to each of an NPN transistor, a PIP transistor, and a PNP transistor. Note that hot carriers tend to be generated more easily in a case of an N-type high-concentration impurity region than in a case of a P-type high-concentration impurity region.

Note also that the MOS thin-film transistor 1 has a lateral structure in which the regions 3 through 6 are arranged in order in a plane which is parallel to a surface of the glass substrate. A transistor having the lateral structure has an advantage of having a small self-parasitic capacitance.

Subsequently, a gate insulating film such as a silicon dioxide (SiO₂) film is formed on the foundation insulating film and the polysilicon film 2, and then a gate electrode 7 is formed on the gate insulating film. The gate electrode 7 has a gate length corresponding to a distance from a boundary between the high-concentration impurity region 3 and the low-concentration impurity region 6 to a boundary between the high-concentration impurity region 4 and the channel region 5, and (i) the low-concentration impurity region 6 and the channel region 5 and (ii) the gate electrode 7 overlap each other (see (a) of FIG. 1). Namely, the thin-film transistor in accordance with the present invention has a one-sided GOLD structure in which (i) the gate electrode and (ii) the low-concentration impurity region (6) provided only on one side of the channel region face and overlap each other, unlike a conventional GOLD structure in which (i) a gate electrode and (ii) low-concentration impurity regions provided on both sides of a channel region face and overlap each other.

Alternatively, a thin-film transistor in accordance with the present invention has a one-sided LDD structure in which a gate electrode and a low-concentration impurity region (6) do not overlap each other but the gate electrode and a channel region (5) merely overlap each other (see (b) of FIG. 1).

As such, the gate electrode of the thin-film transistor in accordance with the present invention has a shorter gate length and a smaller area than those of the conventional thin-film transistor.

As specifically described later, a parasitic capacitance of smaller than a conventional one is generated in an arrangement in which a gate electrode and an electrode of another circuit or a wire face each other, as in a case where a thin-film transistor is (i) provided in each of pixels which constitute a display screen of a display device and (ii) covered with a corresponding pixel electrode. This causes the thin-film transistor to be less affected by a signal supplied to the electrode of the another circuit, and consequently to be stabilized.

(Reason Why a Single Low-concentration Impurity Region is Sufficient)

As described earlier, the reason why a single low-concentration impurity region is sufficient is that the thin-film transistor of the present invention is used in a path in which a current flows in a given single direction. According to the examples of (a) and (b) of FIG. 1, an electric potential of a terminal via which a constant power supply voltage VDD is applied is constantly higher than that of a terminal (OUT) via which a current is outputted (this is to be described later again as operation of the photodetector circuit). This causes the current of the thin-film transistor 1 to constantly flow in a direction pointing from the high-concentration impurity region 3 to the high-concentration impurity region 4.

According to the thin-film transistor 1, the impurity is of N-type. This causes electrons which are carriers to move in a direction opposite to the direction in which the current flows. Namely, the electrons move from the high-concentration impurity region 3 to a conducting wire via which the power supply voltage VDD is applied. As such, the high-concentration impurity region 3 serves as the drain and the high-concentration impurity region 4 serves as the source.

Note that, in a case where the thin-film transistor 1 is arranged, for example, to be a PIP transistor by use of a P-type impurity, an electric potential of a terminal via which a power supply voltage (VSS) is applied is constantly lower than that of a terminal (OUT) via which the current is outputted. In such a PIP transistor, the high-concentration impurity region 3 serves as the drain, and electron holes which are carriers move from the high-concentration impurity region 4 to a conductive wire via which the power supply voltage (VSS) is applied.

It is known that, according to an MOS field effect transistor such as the thin-film transistor 1, since an electric field in the vicinity of the drain has an enhanced intensity, a hot carrier injection phenomenon is caused. Since the carriers (electrons or electron holes), which have moved into a region where the electric field has the enhanced intensity, are accelerated by a high electric field, the carriers obtain a large quantity of energy. This causes a part of the carriers to be hot carriers which have a large quantity of energy enough to cross an electric potential barrier between the polysilicon film 2 and the gate insulating film. These hot carriers are injected into the gate insulating film, and a part of the hot carriers are trapped (captured) in the gate insulating film, so as to cause a space charge. This causes a deterioration, with time, of characteristics of the thin-film transistor such as a threshold voltage and a transfer conductance. Such a deterioration may deteriorate characteristics of a semiconductor device, and ultimately cause a breakdown in the semiconductor device.

Accordingly, a concentration gradient of the impurity occurring between the high-concentration impurity region 3 and the channel region 5 is reduced by providing the LDD structure on the drain side of the thin-film transistor 1 so that a generation of the hot carriers is prevented. This allows a reduction in phenomenon in which an electric field is concentrated at an end of the drain. The reason why the provision of a single low-concentration impurity region is sufficient is thus described.

(Display Device in which Photodetector Circuit is Included)

According to the display device in accordance with the present invention, a photodetector circuit in which the thin-film transistor 1 having the one-sided LDD structure or the one-sided GOLD structure is used is included.

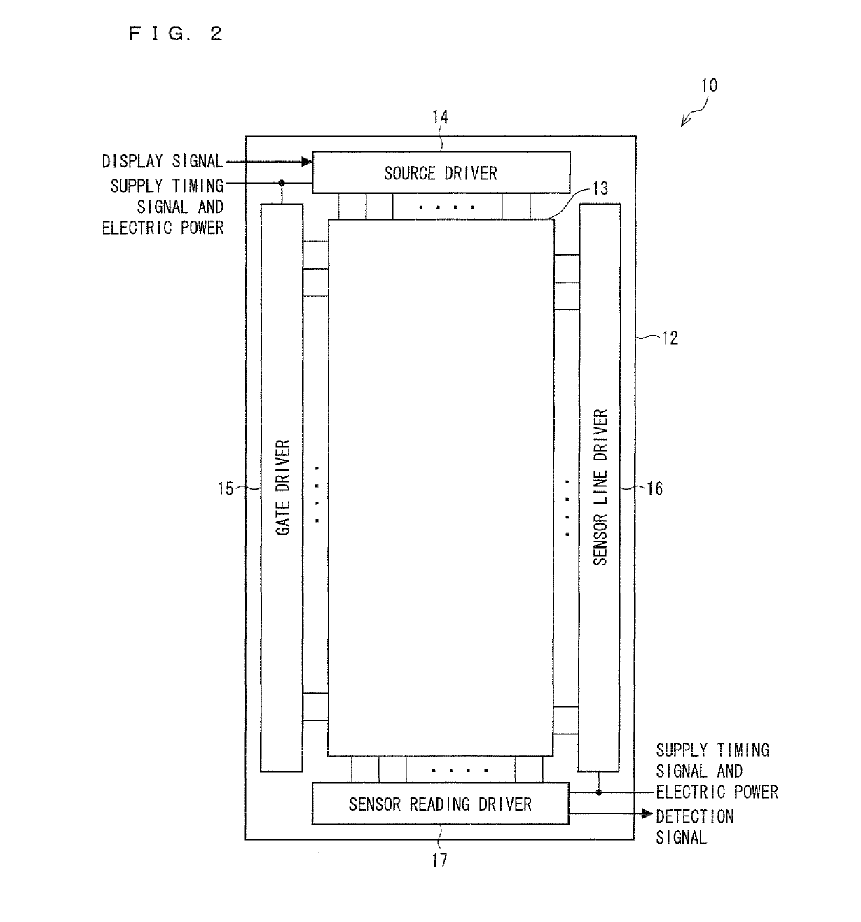

First, the following description discusses a schematic arrangement of the display device. A display device 10 in accordance with the present invention includes a transparent substrate 12 on which various drivers and all the circuit elements constituting each of pixels are integrated (see FIG. 2). The transparent substrate 12 is made, for example, of glass. The display device 10 includes an active matrix region 13, a source driver 14, a gate driver 15, a sensor line driver 16, and a sensor reading driver 17.

According to the active matrix region 13, source signal lines and scanning signal lines are provided in a matrix pattern, and widely known elements which constitute each of the pixels such as a switching element for driving a corresponding one of the pixels and a corresponding pixel electrode are provided at each of intersections of the source signal lines and the scanning signal lines. Note that photodetector circuits are provided in the respective pixels.

The source driver 14 supplies display signals via the respective source signal lines, and the gate driver 15 supplies pixel selection signals via the respective scanning signal lines.

The sensor line driver 16 selectively drives, for each line, corresponding ones of the photodetector circuits. The sensor reading driver 17 applies, to the respective photodetector circuits, the constant electric potential VDD, and reads out photodetection signals from the respective photodetector circuits.

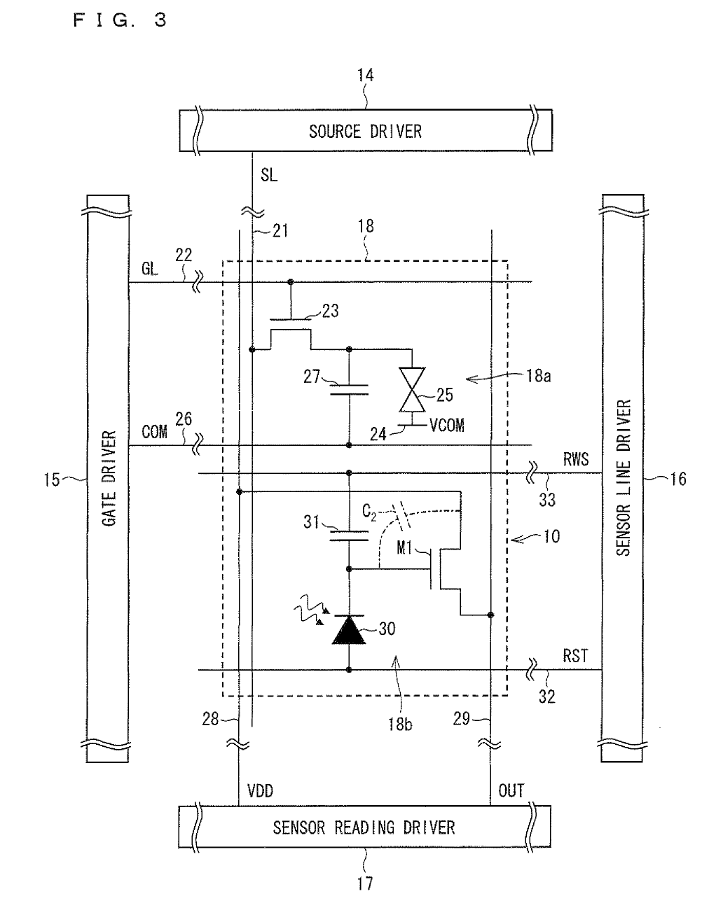

FIG. 3 illustrates a circuit configuration of a pixel circuit 18 provided in one (1) of the pixels constituting the active matrix region 13. The pixel circuit 18 includes a display circuit 18a and a photodetector circuit 18b. Note that the display circuits 18a are provided in the respective pixels, whereas it is not always necessary to provide photodetector circuits 18b in the respective pixels but it is only necessary to provide the photodetector circuits 18b in respective pixels which need them (e.g., for every given number of pixels) in view of a resolution required for photodetection.

The display circuits 18a, which are provided at or in the vicinity of intersections of source signal lines 21 and gate signal lines 22 which are provided vertically and transversely (in a column direction and in a row direction), respectively. The display circuit 18a includes (i) a TFT 23, (ii) a liquid crystal capacitor 25 which is defined by (a) a pixel electrode connected to one end of the TFT 23 and (b) a common electrode 24 which is provided so as to face the pixel electrode, and (iii) a storage capacitor 27 which is defined by the pixel electrode and a common signal line 26.

In contrast, the photodetector circuit 18b is configured to be a circuit of 1T-type (T is an abbreviation of “transistor”) in which only one (1) transistor is used, A TFT: M1 (switching means, a source follower transistor), which is the thin-film transistor of the present invention having the one-sided GOLD structure (see (a) of FIG. 1) or the thin-film transistor of the present invention having the one-sided LDD structure (a source follower TFT having the LDD structure only on a drain side of the source follower TFT) (see (b) of FIG. 1), serves as the source follower transistor. A drain and a source of the TFT: M1 are connected to a power supply line 28 and an output signal line 29, respectively. The power supply line 28 and the output signal line 29 are connected to the sensor reading driver 17, from which the power supply voltage VDD is applied to the power supply line 28.

The TFT: M1 has a gate which is connected to (i) a cathode (a third electrode) of a photodiode 30 and (ii) one end (a second electrode) of an integral capacitor 31 connected in series to the photodiode 30.

An anode (a fourth electrode) of the photodiode 30 is connected to a reset signal line (an initialization signal input line) 32 via which a reset signal RST is supplied by the sensor line driver 16. The other end (a first electrode) of the integral capacitor 31 is connected to a row selection signal line (a selection signal input line) 33 via which a row selection signal RWS is supplied. Note that the row selection signal RWS has a function of (i) selecting photodetector circuits belonging to a corresponding specific one of the rows which are provided in a matrix manner and (ii) causing the photodetector circuits belonging to the corresponding specific one of the rows to output respective detection signals.

(Operation of Photodetector Circuit; Bright State)

Next, the following description discusses operation of the photodetector circuit 18b. First, the reset signal RST of a high level is supplied from the sensor line driver 16 via the reset signal line 32 so as to reset a gate electric potential VINT of the TFT: M1. This causes a forward voltage to be applied across the photodiode 30 during a reset period (t1 through t2). As such, the integral capacitor 31 is charged, and the gate electric potential VINT gradually rises and finally reaches an initialization electric potential (V_{DDR}).

After the gate electric potential VINT has reached the initialization electric potential, the reset signal RST is switched to a low level. This causes the photodiode 30 to have a cathode electric potential higher than an anode electric potential, and therefore a reverse voltage is applied across the photodiode 30. At this time, the gate electric potential VINT becomes equal to a subtraction of (i) a forward voltage drop (V_{F}) of the photodiode 30 and (ii) a voltage drop (ΔV_{RST}) due to a parasitic capacitance of the photodiode 30 from the initialization electric potential (V_{DDR}).

In this state, during a photodetection period in which the photodiode 30 is exposed to light irradiation (t2 through t3), a photocurrent flows in the photodiode 30, in accordance with the intensity of the light, due to the fact that the reverse voltage is applied across the photodiode 30. This causes electric charge stored by the integral capacitor 31 to be discharged via the reset signal line 32. As such, the gate electric potential VINT gradually falls and finally falls to a detected electric potential corresponding to the light intensity.

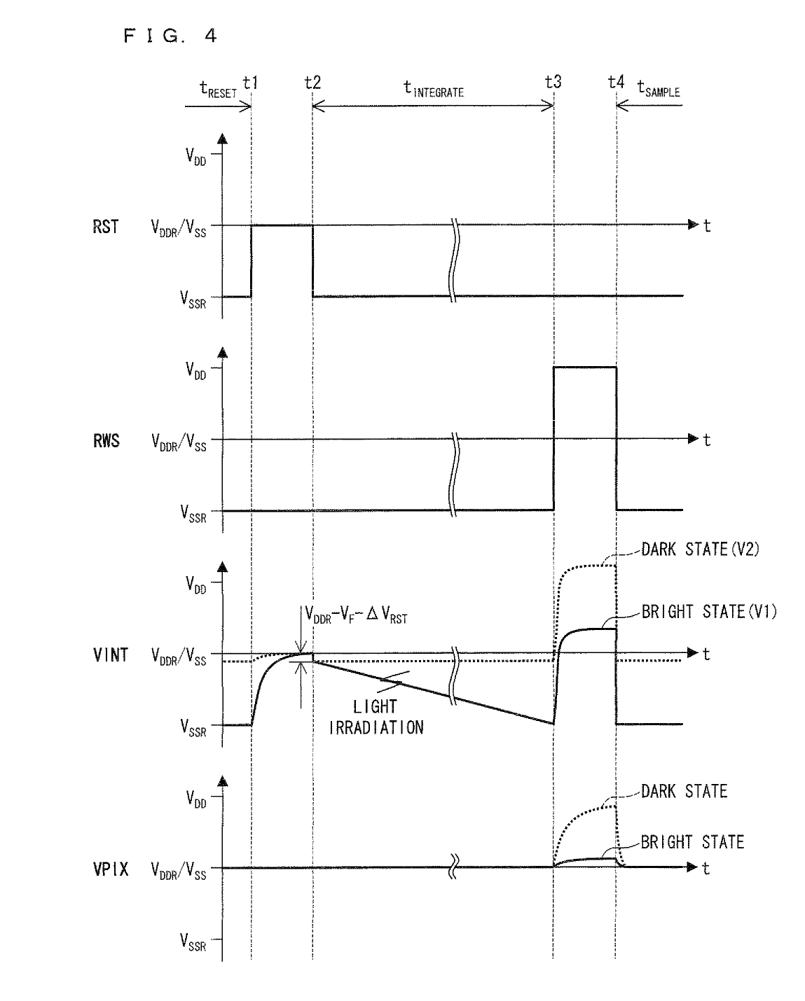

The photodetection period (t2 through t3) is followed by a reading period, i.e., a detection signal reading period (t3 through t4), during which a photodetection result is read out. Thereafter, the row selection signal RWS of a high level is supplied from the sensor line driver 16 via the row selection signal line 33 to the other end of the integral capacitor 31. This causes the gate electric potential VINT to rapidly increase through the integral capacitor 31, so that the gate electric potential VINT reaches an electric potential (for example, an electric potential V1 shown in FIG. 4) which is equal to a sum of the detected electric potential and an electric potential corresponding to the high level of the row selection signal RWS.

Note that the electric potential V1 (see FIG. 4) corresponds to a bright state obtained in a case where the gate electric potential VINT is dropped to a lowest level during t3 after the photodiode 30 receives high-intensity light.

The gate electric potential VINT reaches above a threshold voltage in response to the rapid increase in the gate electric potential VINT. This causes the TFT: M1 to turn on. Accordingly, a voltage, which is amplified in accordance with a gain which varies depending on the gate electric potential VINT (i.e., light intensity), is supplied as a detection signal (e.g., in FIG. 4, VPIX corresponding to a bright state) to the sensor reading driver 17, via the source of the TFT: M1 and the output signal line 29.

(Operation of Photodetector Circuit; Dark State)

In contrast, in a case where the photodiode 30 is exposed to no light irradiation during the photodetection period (t2 through t3), no photocurrent is generated in the photodiode 30. This causes the gate electric potential VINT to substantially retain the initialization electric potential. Note, however, that the gate electric potential VINT becomes a detected electric potential slightly smaller than the initialization electric potential. This is because the photodiode 30 actually generates a small leak current.

The photodetection period (t2 through t3) is followed by the detection signal reading period (t3 through t4), during which the gate electric potential VINT rapidly increases through the integral capacitor 31, similarly to the case of the bright state, so that the gate electric potential VINT reaches an electric potential (for example, an electric potential V2 shown in FIG. 4) which is equal to a sum of the detected electric potential and an electric potential corresponding to the high level of the row selection signal RWS.

At this time, the detection signal supplied from the TFT: M1 (e.g., VPIX in a dark state (see FIG. 4)) shows the highest level.

Thus, the detection signal is generated so as to have a level which varies depending on intensity of the light received by the photodiode 30. Note that the detection signal is generated in each of the pixels in which the respective photodetector circuits 18b are provided. Accordingly, it is possible to carry out detecting operations with respect to an object which is to be detected and is disposed closely to the display screen, by use of a backlight device which the display device 10 shown in FIG. 2 includes as a displaying light source. The detecting operations include reading, on the display screen of the display device 10, of coordinates, characters, and fingerprints.

The TFT: M1 having the one-sided LDD structure or the one-sided GOLD structure of the present invention (already described) causes the detecting operations to be carried out stably and more accurately. This is because a parasitic capacitance defined by a gate electrode of the TFT: M1 and the pixel electrode constituting the liquid crystal capacitor 25 is reduced so that the characteristics of the TFT: M1 such as the threshold voltage are stabilized and less likely to fluctuate with time.

Furthermore, since the TFT: M1 has the one-sided LDD structure or the one-sided GOLD structure of the present invention, the TFT: M1 has a smaller capacitance. This causes a reduction in load on the power supply line 28 and the output signal line 29 to each of which the TFT: M1 is connected. This allows the sensor reading driver 17 to read, in a shorter time, the detection signal supplied from the photodetector circuit 18b. A reduction in the time required to read the detection signal is greatly advantageous for the purpose of realizing a higher resolution in photodetection.

The aforementioned effect is more remarkable in the one-sided LDD structure in which a gate electrode needs not be large than in the one-sided GOLD structure. Namely, since the gate electrode 7 and the low-concentration impurity region 6 do not overlap each other (see (b) of FIG. 1), the gate electrode 7 can be smaller in the arrangement of (b) of FIG. 1 than in the arrangement of (a) of FIG. 1. This allows a reduction in parasitic capacitance defined by the gate electrode 7 and the pixel electrode.

In addition, the arrangement of (b) of FIG. 1 has no parasitic capacitance C₁ which is defined by the gate electrode 7 and the low-concentration impurity region 6 in the arrangement of (a) of FIG. 1 (see (b) of FIG. 1). This causes a reduction in parasitic capacitance C₂ defined by (a) the power supply line 28 to which the TFT: M1 is connected and (b) the gate electrode 7 (i.e., a connecting portion (node) of the gate of the TFT: M1, the cathode of the photodiode 30, and the one end of the integral capacitor 31). This allows a further reduction in influence of a display signal on the gate electric potential VINT.

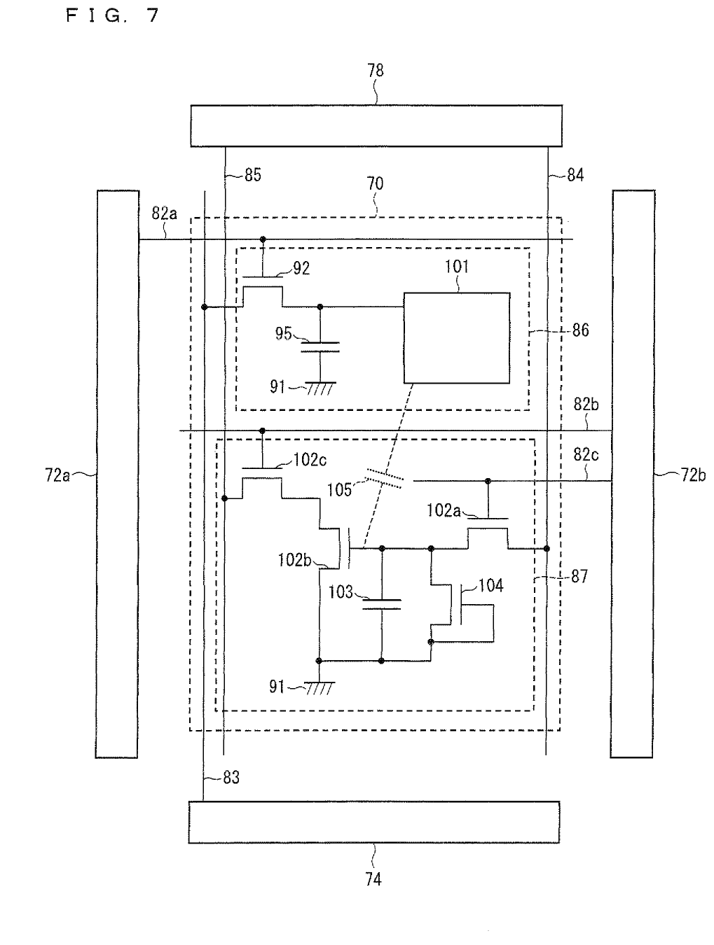

Further, the photodetector circuit 18b includes a much smaller number of elements as compared to the conventional CMOS photodetector circuit as described earlier with reference to FIG. 7. This reduces an area, in the pixel, which is occupied by the photodetector circuit 18b. Therefore, the photodetector circuit 18b of 1T-type is greatly advantageous for the purpose of increasing an aperture ratio of the pixel. Note that the reduction in parasitic capacitance C₂ further causes an increase in response speed of the detecting operations and it is possible to remedy a problem that feed-through of a parasitic capacitance causes a reduction in dynamic range.

As described earlier, when a display device is arranged such that a photodetector circuit of 1T-type is constituted by the thin-film transistor having the one-sided LDD structure or the one-sided GOLD structure of the present invention and then the photodetector circuit of 1T-type is provided in each of the pixels, it is possible to provide an excellent display device in which photodetection is carried out highly accurately, detection characteristics are stabilized with time, and a bright display is carried out.

(Example of Layout of Photodetector Circuit in Pixel)

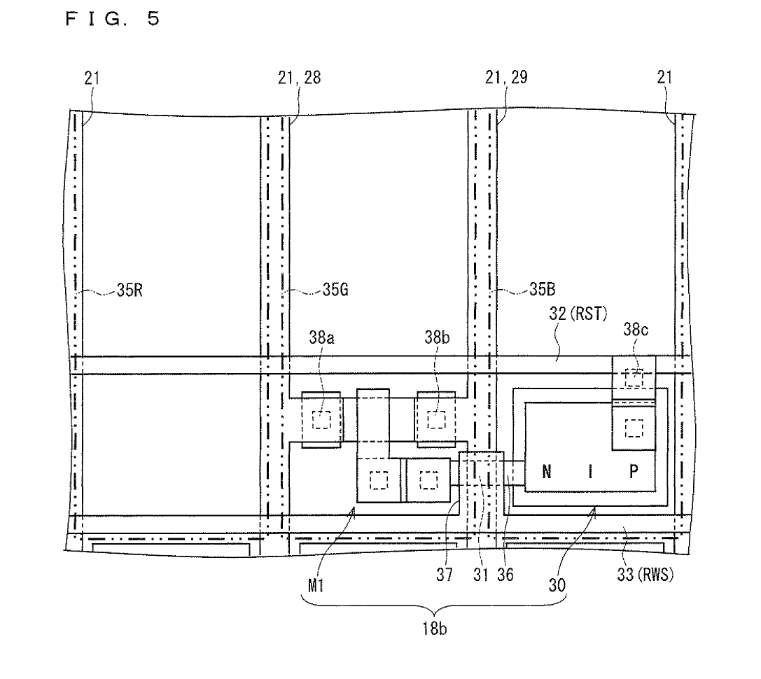

The following description discusses, with reference to FIG. 5, an example of how elements are laid out in a case where the photodetector circuit 18b is provided in a pixel of a liquid crystal display device in which a full-color display is carried out.

FIG. 5 is an enlarged plan view schematically illustrating the vicinity of the photodetector circuit 18b in one (1) pixel constituted by subpixels 35R, 35G, and 35B of three colors of red, green, and blue (RGB).

The subpixels 35R, 35G, and 35B include respective pixel circuits 18 (not illustrated in FIG. 5). Source signal lines 21 extend in a column direction between the respective subpixels 35R, 35G, and 35B which are adjacent to each other in a row direction, and supply display signals of respective colors to the TFTs 23 (see FIG. 3) of the respective pixel circuits 18.

Note that, according to the arrangement illustrated in FIG. 5, the source signal line 21 provided between the subpixels 35R and 35G concurrently serves as the power supply line 28, and the source signal line 21 provided between the subpixels 35G and 35B concurrently serves as the output signal line 29.

The photodetector circuits 18b are provided in one end side regions of the respective subpixels 35R, 35G, and 35B in the column direction. The end side regions are defined by the adjacent source signal lines 21, the reset signal line 32, and the row selection signal line 33 which extend orthogonal to the source signal lines 21. Note that the reset signal line 32 and the row selection signal line 33 are provided so as to be away from each other, in the column direction, by a certain distance.

According to the arrangement illustrated in FIG. 5, the TFT: M1 which constitutes the photodetector circuit 18b is provided in the one end side region of the subpixel 35G, and the photodiode 30 is provided in the one end side region of the subpixel 358. A line 36 connecting the gate of the TFT: M1 and the cathode (an N-layer) of the photodiode 30 is provided, for example, below the source signal line 21 between the subpixels 35G and 35B, and an extended part 37 which is a part of the row selection signal line 33 extends above the line 36. Since the line 36 and the extended part 37 partially overlap each other, the integral capacitor 31 is formed. Note that the line 36 can be made, for example, of Si.

The drain of the TFT: M1 is connected via a contact section 38a to the source signal line 21 which concurrently serves as the power supply line 28, and the source of the TFT: M1 is connected via a contact section 38b to the source signal line 21 which concurrently serves as the output signal line 29. The anode (a P-layer) of the photodiode 30 is connected via a contact section 38c to the reset signal line 32.

The photodetector circuit 18b includes a much smaller number of elements as compared to the conventional CMOS photodetector circuit illustrated in FIG. 7 (see FIG. 5). This shows that the photodetector circuit 18b contributes to an increase in aperture ratio and allows a bright display.

Note that a photodetector element such as a thin-film photodiode made of low-temperature polysilicon (LPS) has a property of being relatively highly sensitive to blue light and relatively less sensitive to red light. Due to such a property, the provision of a photodetector element in a red pixel causes a disadvantage of narrowing a dynamic range because the photodetector element has a low sensitivity but causes an advantage of improving a signal quality because the photodetector element reads no stray light entering into a pixel. In contrast, the provision of a photodetector element in a blue pixel causes an advantage of widening a dynamic range because the photodetector element has a high sensitivity but causes a disadvantage of deteriorating a signal quality because the photodetector element is highly likely to read stray light.

(Variations of Photodetector Circuit)

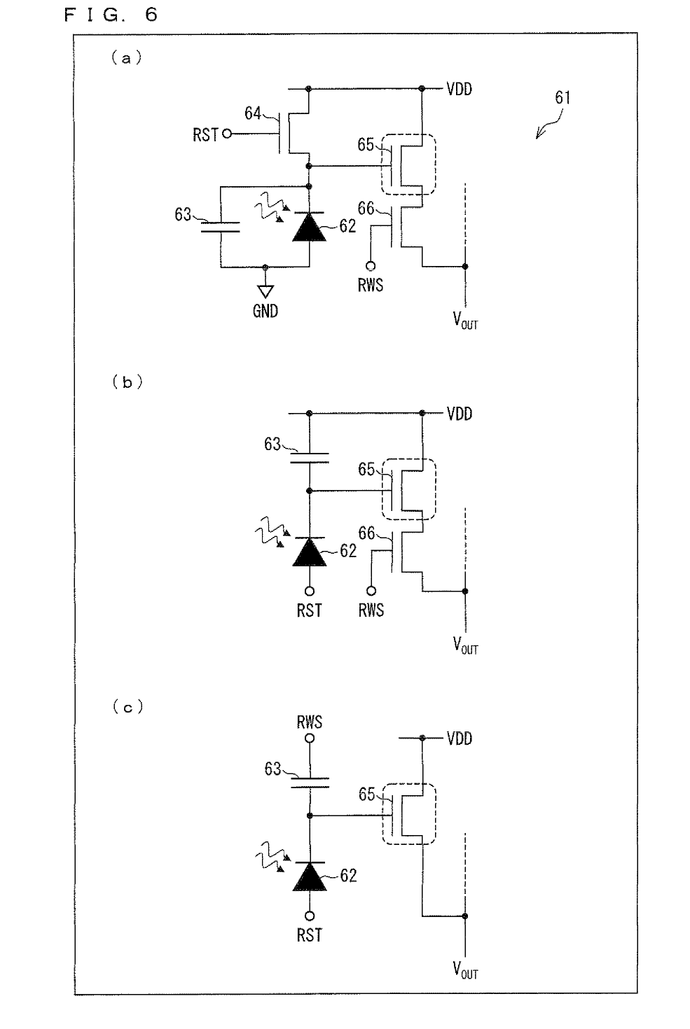

FIG. 6 illustrates variations of the photodetector circuit 18b to which a TFT serving as a source follower having the GOLD structure of the present invention is applicable. In each of (a) through (c) of FIG. 6, a TFT 65 (described later) has the one-sided LDD structure or the one-sided GOLD structure of the present invention.

(c) of FIG. 6 illustrates a photodetector circuit of 1T-type having an arrangement identical to the arrangement of the photodetector circuit 18b as described earlier with reference to FIGS. 3 through 5. Namely, a correspondence between (a) the elements of the photodetector circuit 18b (see FIG. 3) and (b) elements of the photodetector circuit of 1T-type (see (c) of FIG. 6) is as follows:

Photodiode 30 - - - Photodiode 62

Integral capacitor 31 - - - Integral capacitor 63

TFT: M1 - - - TFT 65 (Switching means, Source follower transistor)

In contrast, (a) of FIG. 6 illustrates a photodetector circuit having an arrangement similar to the arrangement of the conventional CMOS photodetector circuit as described earlier with reference to FIG. 7, and the photodetector circuit is arranged as a circuit of 3T-type in which three transistors are used. A correspondence between (a) elements of the photodetector circuit of 3T-type (see (a) of FIG. 6) and (b) the elements of the photodetector pixel 87 (see FIG. 7) is as follows:

Photodiode 62 - - - TFT 104

Integral capacitor 63 - - - Integral capacitor 103

TFT 64 - - - TFT 102a (Initialization Transistor)

TFT 65 - - - TFT 102b (Switching means, Source follower transistor)

TFT 66 - - - TFT 102c (Switching transistor)

Note that a power supply voltage VDD of (a) of FIG. 6 and a constant voltage applied to the common signal line 91 of FIG. 7 correspond to each other. The operation of the photodetector circuit of 3T-type has been already described with reference to FIG. 7 and is therefore not described here.

(b) of FIG. 6 illustrates a photodetector circuit of 2T-type in which two transistors are employed by removing one (1) element from the photodetector circuit of 3T-type so that the aperture ratio is improved.

Specifically, according to the photodetector circuit of 2T-type, a TFT 64 to which on/off control is carried out in response to a reset signal RST is removed from the photodetector circuit of 3T-type, one electrode (a second electrode) of an integral capacitor 63 is connected to a gate of a TFT 65 and a cathode (a third electrode) of a photodiode 62, and the other electrode (a first electrode) of the integral capacitor 63 is connected to a power supply line through which a power supply voltage VDD is supplied. An anode (a fourth electrode) of the photodiode 62 is supplied with a reset signal RST, which is similar to the case of a photodiode 62 of the photodetector circuit of 1T-type.

The following description discusses operation of the photodetector circuit of 2T-type. First, in order to reset a gate electric potential VINT of the TFT 65, the reset signal RST of a high level which is equivalent to the power supply voltage VDD is supplied to the anode of the photodiode 62. This causes a forward voltage to be applied across the photodiode 62 during a reset period. The gate electric potential VINT reaches an initialization electric potential equal to a subtraction of (i) a forward voltage drop of the photodiode 62 from the power supply voltage VDD.

In a case where the level of the reset signal RST is switched to a low level (e.g., 0V) after the gate electric potential VINT has reached the initialization electric potential, the photodiode 62 has a cathode electric potential which is higher than an anode electric potential. This causes a reverse voltage to be applied across the photodiode 62. In this state, during a photodetect on period in which the photodiode 62 is exposed to light irradiation, a photocurrent flows in the photodiode 62, in accordance with the intensity of the light, due to the fact that the reverse voltage is applied across the photodiode 62. This causes electric charge to be stored in the integral capacitor 63, and therefore the gate electric potential VINT is equal to a subtraction of a voltage applied across the integral capacitor 63 from the power supply voltage VDD. Namely, the gate electric potential VINT falls in accordance with the intensity of the light.

Subsequently, a row selection signal RWS of a high level is supplied to a gate of the TFT 66 during a detection signal reading period. This causes the TFT 66 to turn on. Therefore, a voltage which corresponds to a level of the gate electric potential VINT, i.e., a voltage which is amplified in accordance with a gain which varies depending on the intensity of the light is supplied from a source of the TFT 66 as a detection signal.

As described earlier, a photodetector circuit of 2T-type, which has a smaller number of elements than a photodetector circuit of 3T-type, is advantageous for the purpose of increasing the aperture ratio of the pixel. In addition, a thin-film transistor having the one-sided LDD structure or the one-sided GOLD structure of the present invention is used in the photodetector circuit of 2T-type. This makes it possible to similarly obtain effects of (i) an increase in response speed of detecting operations and (ii) an increase in dynamic range.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below. An embodiment based on a proper combination of technical means disclosed in different embodiments is encompassed in the technical scope of the present invention.

As described earlier, a thin-film transistor in accordance with the present invention which (i) is used in a path in which a current flows in a given single direction and (ii) has first and second high-concentration impurity regions which are provided on both sides of a channel region, the thin-film transistor further has a low-concentration impurity region which is provided to be sandwiched only between (i) one of the first and second high-concentration impurity regions into which carriers corresponding to a polarity of the first and second high-concentration impurity regions move in accordance with the given single direction and (ii) the channel region. Alternatively, the thin-film transistor in accordance with the present invention includes a structure in which a gate electrode of the thin-film transistor and the low-concentration impurity region are provided so as to face and overlap each other.

With the arrangement, it is possible to further reduce an area of a gate electrode as compared to a thin-film transistor having a GOLD structure in which low-concentration impurity regions are provided on both sides of a channel region. This causes a smaller parasitic capacitance to be generated in an arrangement in which a gate electrode and an electrode of another circuit face each other. This brings about an effect of stabilizing of a thin-film transistor.

As described earlier, a photodetector circuit in accordance with the present invention includes a photodetector element, the thin-film transistor as mentioned above being used as switching means for causing a voltage which varies in accordance with an amount of light received by the photodetector element to be outputted.

This brings about the following various effects of (i) being capable of stably carrying out detection of an amount of light because the photodetector circuit of the present invention includes the thin-film transistor having the one-sided LDD structure or the one-sided GOLD structure in which a gate electrode has a small area, (ii) achieving a quick response speed at which the photodetector circuit detects an amount of received light because a parasitic capacitance, defined by a gate electrode and an electrode of another circuit or a wire which faces the gate electrode, is reduced, (iii) widening a dynamic range because a feed-through voltage due to a parasitic capacitance is reduced, and (iv) contributing to high-resolution photodetection because a detection signal supplied from a photodetector element can be read in a shorter time.

A display device in accordance with the present invention includes the photodetector circuit as mentioned above provided in each of part or all of a plurality of pixels which constitute a display screen, in the each of part or all of the plurality of pixels in which the photodetector circuit is provided, the photodetector circuit being covered with a corresponding pixel electrode via which a display signal is supplied.

This brings about an effect of widening a dynamic range because, in a display device, (i) various functions each caused by utilizing a photodetector are stabilized and (ii) a response speed of each of the various functions becomes faster.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

### INDUSTRIAL APPLICABILITY

The present invention is applicable to (i) a thin-film transistor which is required to have a stable ON characteristic, (ii) a photodetector circuit including the thin-film transistor as an output controlling transistor, and (iii) a display device in which the photodetector circuit is provided in a pixel.

1. A thin-film transistor which (i) is used in a path in which a current flows in a given single direction and (ii) has first and second high-concentration impurity regions which are provided on both sides of a channel region,
said thin-film transistor further having a low-concentration impurity region which is provided to be sandwiched only between (i) one of the first and second high-concentration impurity regions into which carriers corresponding to a polarity of the first and second high-concentration impurity regions move in accordance with the given single direction and (ii) the channel region.

2. The thin-film transistor as set forth in claim 1, wherein a gate electrode of the thin-film transistor and only the channel region are provided so as to overlap each other.

3. The thin-film transistor as set forth in claim 1, wherein a gate electrode of the thin-film transistor and the low-concentration impurity region are provided so as to face and overlap each other.

4. A photodetector circuit comprising a photodetector element,
the thin-film transistor recited in claim 1 being used as switching means for causing a voltage which varies in accordance with an amount of light received by the photodetector element to be outputted.

5. The photodetector circuit as set forth in claim 4, wherein the thin-film transistor used as the switching means functions as a source follower transistor.

6. The photodetector circuit as set forth in claim 4, further comprising:
a capacitor having a first electrode which is connected to a selection signal input line,
the photodetector element being a photodiode having (i) a third electrode which is connected to a gate of the thin-film transistor used as the switching means and to a second electrode of the capacitor and (ii) a fourth electrode which is connected to an initialization signal input line,
the fourth electrode being arranged to (i) receive, during a reset period, a first voltage which causes a forward voltage to be applied across the photodiode so that the capacitor is charged until a set voltage is applied across the capacitor and (ii) receive, during a photodetection period, a second voltage which causes a reverse voltage to be applied across the photodiode,
the first electrode of the capacitor being arranged to receive, during a detection signal reading period, from the selection signal input line, a third voltage which causes a rapid increase in electric potential of the gate.

7. The photodetector circuit as set forth in claim 4, further comprising:
a capacitor having a first electrode to which a constant voltage is applied; and
a switching transistor having (i) a drain-source electroconductive path which is connected in series to a drain-source electroconductive path of the thin-film transistor used as the switching means and (ii) a gate which is connected to a selection signal input line,
the photodetector element being a photodiode having (i) a third electrode which is connected to a gate of the thin-film transistor and to a second electrode of the capacitor and (ii) a fourth electrode which is connected to an initialization signal input line,
the fourth electrode being arranged to (i) receive, during a reset period, a first voltage which causes a forward voltage to be applied across the photodiode so that the capacitor is charged until a set voltage is applied across the capacitor and (ii) receive, during a photodetection period, a second voltage which causes a reverse voltage to be applied across the photodiode,
a voltage, which varies in accordance with an amount of light received by the photodiode, being supplied from the thin-film transistor via the switching transistor, during a detection signal reading period, in response to a third voltage which causes the switching transistor to turn on, being supplied from the selection signal input line.

8. The photodetector circuit as set forth in claim 4, further comprising:
a switching transistor having (i) a drain-source electroconductive path which is connected in series to a drain-source electroconductive path of the thin-film transistor used as the switching means and (ii) a gate which is connected to a selection signal input line,
the photodetector element being the photodiode which is connected to a capacitor in parallel, each end of the photodiode and the capacitor being grounded,
said photodetector circuit, further comprising,
an initialization transistor having (i) source-drain connected between the other end of the photodiode and a power supply voltage whose electric potential is higher than a ground electric potential and (ii) a gate connected to an initialization signal input line,
the capacitor being charged by the power supply voltage and a reverse voltage is applied across the photodiode, during a reset period, while the initialization transistor is turning on in response to a signal supplied from the initialization signal input line, and a voltage which varies in accordance with an amount of light received by the photodiode being supplied from the thin-film transistor via the switching transistor while the switching transistor is turning on in response to a signal supplied from the selection signal input line.

9. A display device comprising the photodetector circuit recited in claim 4 provided in each of part or all of a plurality of pixels which constitute a display screen,
in the each of part or all of the plurality of pixels in which the photodetector circuit is provided, the photodetector circuit being covered with a corresponding pixel electrode via which a display signal is supplied.

10. The display device as set forth in claim 9, wherein:
a single photodetector circuit is provided for every given number of pixels which are adjacent to each other; and
a plurality of elements which constitute the single photodetector circuit are dispersed in the given number of plurality of pixels.
